(19) United States
(12) Patent Application Publication
(10) Pub. No.: US 2026/0114066 A1
(43) Pub. Date: Apr. 23, 2026

(54) PHOTODETECTOR, ELECTRONIC APPARATUS, AND OPTICAL ELEMENT

(71) Applicant: SONY SEMICONDUCTOR SOLUTIONS CORPORATION, Kanagawa (JP)

(72) Inventor: Nao YOSHIMOTO, Kanagawa (JP)

(73) Assignee: SONY SEMICONDUCTOR SOLUTIONS CORPORATION, Kanagawa (JP)

(21) Appl. No.: 19/118,728

(22) PCT Filed: Oct. 24, 2023
(86) PCT No.: PCT/JP2023/038365

§ 371 Date: Apr. 4, 2025

(30) Foreign Application Priority Data
Nov. 1, 2022 (JP) 2022-175800

(51) Int. Cl. H10F 39/00

(52) U.S. Cl. CPC H10F 39/806; H10F 39/8053

(57) ABSTRACT

There is provided a photodetector. The photodetector includes a light-guide including a structure including a first section having a size equal to or less than a wavelength of incident light and a second section provided below the first section. A first material is provided next to the first section and has a refractive index different from a refractive index of the structure and a second material is provided next to the second section and has a refractive index different from the refractive index of the structure. A first photoelectric converter photoelectrically converts the incident light via the light-guide. The first section is in contact with the second section.

### CROSS REFERENCE TO RELATED APPLICATIONS

This application claims the benefit of Japanese Priority Patent Application JP2022-175800 filed Nov. 1, 2022, the entire contents of which are incorporated herein by reference.

### TECHNICAL FIELD

The present disclosure relates to a photodetector, an electronic apparatus, and an optical element.

### BACKGROUND ART

A meta-optical element including a plurality of nanostructures and a peripheral material having a refractive index different from that of the plurality of nanostructures has been proposed (PTL 1).

### CITATION LIST

### Patent Literature

[PTL 1] Japanese Unexamined Patent Application Publication No. 2021-140152

### SUMMARY

### Technical Problem

It is desired, for a device that detects light, to improve detection performance.

It is desirable to provide a photodetector having favorable detection performance.

### Solution to Problem

A photodetector according to an embodiment of the present disclosure includes: a light-guiding section including a structure including a first section having a size equal to or less than a wavelength of incident light and a second section provided below the first section, a first material provided next to the first section and having a refractive index different from a refractive index of the structure, and a second material provided next to the second section and having a refractive index different from the refractive index of the structure; and a first photoelectric conversion section that photoelectrically converts light incident via the light-guiding section. The first section is in contact with the second section.

An electronic apparatus according to an embodiment of the present disclosure includes an optical system, and a photodetector that receives light transmitted through the optical system. The photodetector includes: a light-guiding section including a structure including a first section having a size equal to or less than a wavelength of incident light and a second section provided below the first section, a first material provided next to the first section and having a refractive index different from a refractive index of the structure, and a second material provided next to the second section and having a refractive index different from the refractive index of the structure; and a photoelectric conversion section that photoelectrically converts light incident via the light-guiding section. The first section is in contact with the second section.

An optical element according to an embodiment of the present disclosure includes: a structure including a first section having a size equal to or less than a wavelength of incident light and a second section provided below the first section; a first material provided next to the first section and having a refractive index different from a refractive index of the structure; and a second material provided next to the second section and having a refractive index different from the refractive index of the structure. The first section is in contact with the second section.

### BRIEF DESCRIPTION OF DRAWINGS

FIG. 1 is a block diagram illustrating an example of a schematic configuration of an imaging device which is an example of a photodetector according to an embodiment of the present disclosure.

FIG. 2 is a diagram illustrating an example of an arrangement of pixels of the imaging device according to the embodiment of the present disclosure.

FIG. 3 is a diagram illustrating an example of a cross-sectional configuration of the imaging device according to the embodiment of the present disclosure.

FIG. 4A is a diagram illustrating an example of a planar configuration of the imaging device according to the embodiment of the present disclosure.

FIG. 4B is a diagram illustrating an example of the planar configuration of the imaging device according to the embodiment of the present disclosure.

FIG. 4C is a diagram illustrating an example of the planar configuration of the imaging device according to the embodiment of the present disclosure.

FIG. 5 is a diagram illustrating an example of a cross-sectional configuration of the imaging device according to the embodiment of the present disclosure.

FIG. 6A is a diagram illustrating an example of a planar configuration of the imaging device according to the embodiment of the present disclosure.

FIG. 6B is a diagram illustrating another example of a planar configuration of the imaging device according to the embodiment of the present disclosure.

FIG. 7A is a diagram illustrating an example of a method of manufacturing a light-guiding section of the imaging device according to the embodiment of the present disclosure.

FIG. 7B is a diagram illustrating an example of the method of manufacturing the light-guiding section of the imaging device according to the embodiment of the present disclosure.

FIG. 7C is a diagram illustrating an example of the method of manufacturing the light-guiding section of the imaging device according to the embodiment of the present disclosure.

FIG. 7D is a diagram illustrating an example of the method of manufacturing the light-guiding section of the imaging device according to the embodiment of the present disclosure.

FIG. 7E is a diagram illustrating an example of the method of manufacturing the light-guiding section of the imaging device according to the embodiment of the present disclosure.

FIG. 7F is a diagram illustrating an example of the method of manufacturing the light-guiding section of the imaging device according to the embodiment of the present disclosure.

FIG. 7G is a diagram illustrating an example of the method of manufacturing the light-guiding section of the imaging device according to the embodiment of the present disclosure.

FIG. 7H is a diagram illustrating an example of the method of manufacturing the light-guiding section of the imaging device according to the embodiment of the present disclosure.

FIG. 7I is a diagram illustrating an example of the method of manufacturing the light-guiding section of the imaging device according to the embodiment of the present disclosure.

FIG. 8 is a diagram illustrating an example of a cross-sectional configuration of a light-guiding section of an imaging device according to Modification Example 1 of the present disclosure.

FIG. 9 is a diagram illustrating an example of the cross-sectional configuration of the light-guiding section of the imaging device according to Modification Example 1 of the present disclosure.

FIG. 10A is an explanatory diagram of an example of a planar configuration of the light-guiding section of the imaging device according to Modification Example 1 of the present disclosure.

FIG. 10B is an explanatory diagram of another example of a planar configuration of the light-guiding section of the imaging device according to Modification Example 1 of the present disclosure.

FIG. 10C is an explanatory diagram of another example of a planar configuration of the light-guiding section of the imaging device according to Modification Example 1 of the present disclosure.

FIG. 11A is a diagram illustrating another example of the cross-sectional configuration of the light-guiding section of the imaging device according to Modification Example 1 of the present disclosure.

FIG. 11B is a diagram illustrating another example of the cross-sectional configuration of the light-guiding section of the imaging device according to Modification Example 1 of the present disclosure.

FIG. 12A is a diagram illustrating another example of the cross-sectional configuration of the light-guiding section of the imaging device according to Modification Example 1 of the present disclosure.

FIG. 12B is a diagram illustrating another example of the cross-sectional configuration of the light-guiding section of the imaging device according to Modification Example 1 of the present disclosure.

FIG. 13A is a diagram illustrating an example of a cross-sectional configuration of a light-guiding section of an imaging device according to Modification Example 2 of the present disclosure.

FIG. 13B is a diagram illustrating another example of the cross-sectional configuration of the light-guiding section of the imaging device according to Modification Example 2 of the present disclosure.

FIG. 14 is a diagram illustrating another example of the cross-sectional configuration of the light-guiding section of the imaging device according to Modification Example 2 of the present disclosure.

FIG. 15 is a diagram illustrating an example of a cross-sectional configuration of a light-guiding section of an imaging device according to Modification Example 3 of the present disclosure.

FIG. 16 is a diagram illustrating another example of the cross-sectional configuration of the light-guiding section of the imaging device according to Modification Example 3 of the present disclosure.

FIG. 17 is an explanatory diagram of an example of a planar configuration of the light-guiding section of the imaging device according to Modification Example 3 of the present disclosure.

FIG. 18 is a diagram illustrating an example of a cross-sectional configuration of an imaging device according to Modification Example 4 of the present disclosure.

FIG. 19 is a block diagram illustrating a configuration example of an electronic apparatus including the imaging device.

FIG. 20 is a block diagram depicting an example of a schematic configuration of a vehicle control system.

FIG. 21 is a diagram explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

### DESCRIPTION OF EMBODIMENTS

Hereinafter, a description is given in detail of embodiments of the present disclosure with reference to the drawings. It is to be noted that the description is given in the following order.
1. Embodiment
2. Modification Examples
3. Application Example
4. Practical Application Examples

### 1. Embodiment

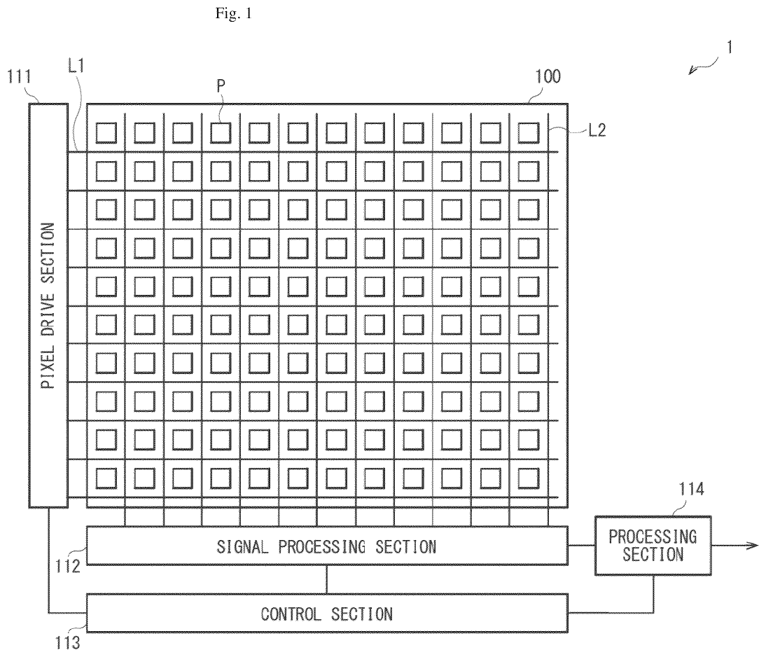

FIG. 1 is a block diagram illustrating an example of a schematic configuration of an imaging device which is an example of a photodetector according to an embodiment of the present disclosure. The photodetector is a device that is able to detect incoming light. An imaging device 1, which is the photodetector, can receive light transmitted through an optical system to generate a signal. The imaging device 1 (photodetector) includes a plurality of pixels P each including a photoelectric conversion section and is configured to photoelectrically convert incident light to generate a signal.

The photoelectric conversion section of each of the pixels P of the imaging device 1 is, for example, a photodiode, and is configured to be able to photoelectrically convert light. The imaging device 1 includes, as an imaging area, a region (a pixel section 100) in which the plurality of pixels P are two-dimensionally arranged in matrix. The pixel section 100 is a pixel array in which the plurality of pixels P are arranged and can also be referred to as a light-receiving region.

The imaging device 1 takes in incident light (image light) from a subject via an optical system (unillustrated) including an optical lens. The imaging device 1 captures an image of the subject formed by the optical lens. The imaging device 1 can photo-electrically convert received light to generate a pixel signal. The imaging device 1 is, for example, a Complementary Metal Oxide Semiconductor (CMOS) image sensor. The imaging device 1 is usable for an electronic apparatus such as a digital still camera, a video camera, or a mobile phone.

As in the example illustrated in FIG. 1, the imaging device 1 includes, in a peripheral region of the pixel section 100 (pixel array), for example, a pixel drive section 111, a signal processing section 112, a control section 113, a processing section 114, and the like. In addition, the imaging device 1 is provided with a plurality of control lines L1 and a plurality of signal lines L2.

The imaging device 1 is provided with the control line L1 which is a signal line that is able to transmit a signal to control the pixel P. In the pixel section 100, for example, the plurality of control lines L1 are wired for respective pixel rows each configured by the plurality of pixels P arranged in a horizontal direction (row direction). The control line L1 is configured to transmit a control signal to read a signal from the pixel P. The control line L1 may be referred to as a pixel drive line that transmits a signal to drive the pixel P.

In addition, the imaging device 1 is provided with a signal line L2 which is a signal line that is able to transmit a signal from the pixel P. In the pixel section 100, for example, signal lines L2 are wired for respective pixel columns each configured by a plurality of pixels P arranged in a vertical direction (column direction). The signal line L2 is a vertical signal line and is configured to transmit a signal output from the pixel P.

The pixel drive section 111 is configured by a shift register, an address decoder, and the like. The pixel drive section 111 is configured to be able to drive each of the pixels P of the pixel section 100. The pixel drive section 111 generates a signal to control the pixel P, and outputs the signal to each of the pixels P of the pixel section 100 via the control line L1.

The pixel drive section 111 generates, for example, a signal to control a transfer transistor of the pixel P, a signal to control a reset transistor, or the like, and supplies the signal to each of the pixels P by the control line L1. The pixel drive section 111 can perform control to read a pixel signal from each of the pixels P. The pixel drive section 111 may also be referred to as a pixel control section configured to be able to control each of the pixels P.

The signal processing section 112 is configured to be able to execute signal processing of an input pixel signal. The signal processing section 112 includes, for example, a load circuit part, an Analog-to-Digital (AD) converter part, a horizontal selection switch, and the like. The signal output from each of the pixels P selected and scanned by the pixel drive section 111 is input to the signal processing section 112 via the signal line L2. The signal processing section 112 performs signal processing such as Correlated Double Sampling (CDS) and AD conversion of the signal of the pixel P. The signal of each of the pixels P transmitted through each of the signal lines L2 is subjected to signal processing by the signal processing section 112, and output to the processing section 114.

The processing section 114 is configured to be able to execute signal processing on an input signal. The processing section 114 is configured by, for example, a circuit that performs various types of signal processing on a pixel signal. The processing section 114 may include a processor and a memory. The processing section 114 performs signal processing on the input pixel signal from the signal processing section 112, and outputs the processed pixel signal. The processing section 114 can perform, for example, various types of signal processing such as noise reduction processing or gradation correction processing.

The control section 113 is configured to control each section of the imaging device 1. The control section 113 can receive a clock signal provided from the outside, data ordering of an operation mode, or the like, and output data such as internal information on the imaging device 1. The control section 113 includes a timing generator configured to generate various timing signals. The control section 113 drives a peripheral circuit such as the pixel drive section 111 and/or the signal processing section 112 based on the various timing signals (pulse signals, clock signals, and the like) generated by the timing generator. It is to be noted that the control section 113 and the processing section 114 may be integrally configured.

The pixel drive section 111, the signal processing section 112, the control section 113, the processing section 114, and the like, may be provided in one semiconductor substrate or may be provided separately in a plurality of semiconductor substrates. The imaging device 1 may have a structure (stacked structure) configured by stacking a plurality of substrates.

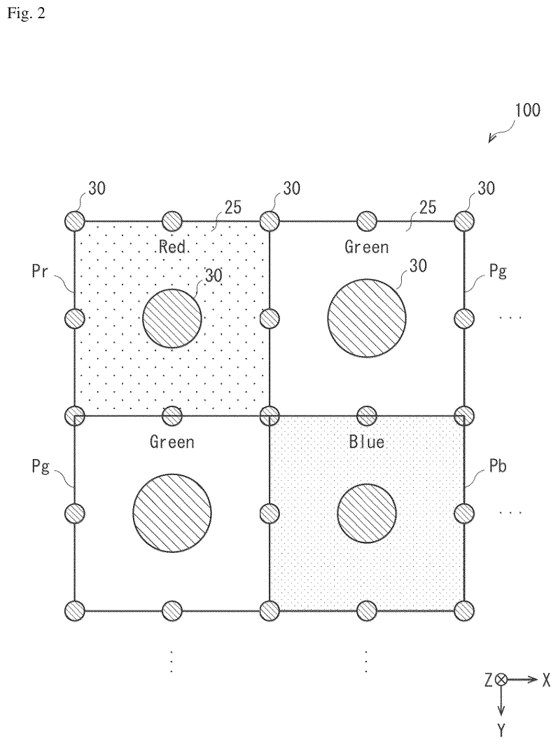

FIG. 2 is a diagram illustrating an example of an arrangement of pixels of the imaging device according to the embodiment. The pixel P of the imaging device 1 includes a color filter 25. In addition, as described later, the pixel P includes a light-guiding section 50 configured using a structure 30. It is to be noted that, as illustrated in FIG. 2, a direction in which light from the subject is incident is defined as a Z-axis direction; a right-left direction on the plane orthogonal to the Z-axis direction is defined as an X-axis direction; and an up-down direction on the plane orthogonal to the Z-axis and the X-axis is defined as a Y-axis direction. In the following drawings, the arrow directions in FIG. 2 may be used, in some cases, as a standard to express a direction.

The color filter 25 is configured to selectively transmit light of a particular wavelength of incoming light. The plurality of pixels P provided in the pixel section 100 of the imaging device 1 includes a plurality of pixels Pr each provided with the color filter 25 that transmits light having a wavelength of red (R) light, a plurality of pixels Pg each provided with the color filter 25 that transmits light having a wavelength of green (G) light, and a plurality of pixels Pb each provided with the color filter 25 that transmits light having a wavelength of blue (B) light.

In the pixel section 100, as in the example illustrated in FIG. 2, the plurality of pixels Pr, the plurality of pixels Pg, and the plurality of pixels Pb are repeatedly arranged. The pixel Pr, the pixel Pg, and the pixel Pb are arranged in accordance with a Bayer arrangement. The pixel Pr, the pixel Pg, and the pixel Pb generate a pixel signal of an R component, a pixel signal of a G component, and a pixel signal of a B component, respectively. The imaging device 1 is able to obtain RGB pixel signals.

It is to be noted that the color filter 25 provided for the pixel P of the pixel section 100 is not limited to a color filter of a primary color system (RGB), and may be a color filter of a complementary color system such as cyan (Cy), (magenta (Mg), or yellow (Ye), for example. In the pixel P that receives white (W) light to perform photoelectric conversion, the color filter 25 may not be provided. In addition, a color filter corresponding to W (white) i.e., a filter that transmits light beams of all wavelengths of incident light may be arranged. It is to be noted that the color filter 25 may be omitted, as needed. For example, depending on characteristics of the light-guiding section 50, the color filter 25 may not be provided in some or all of the pixels P of the imaging device 1.

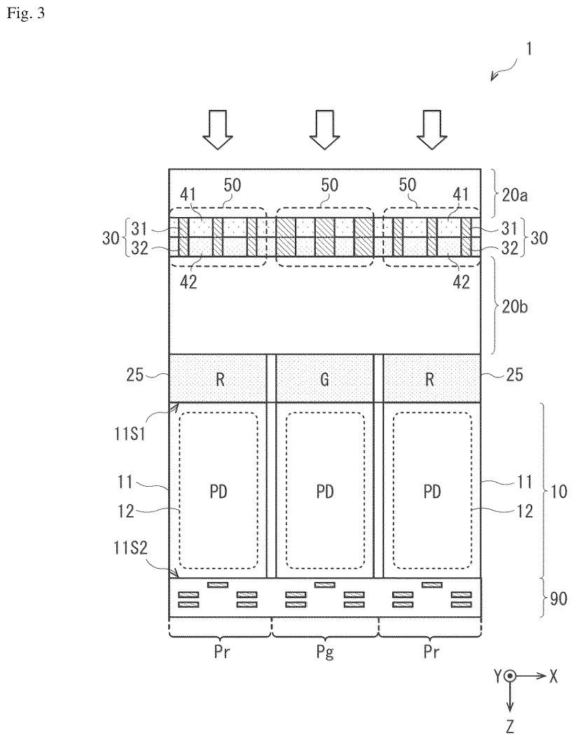

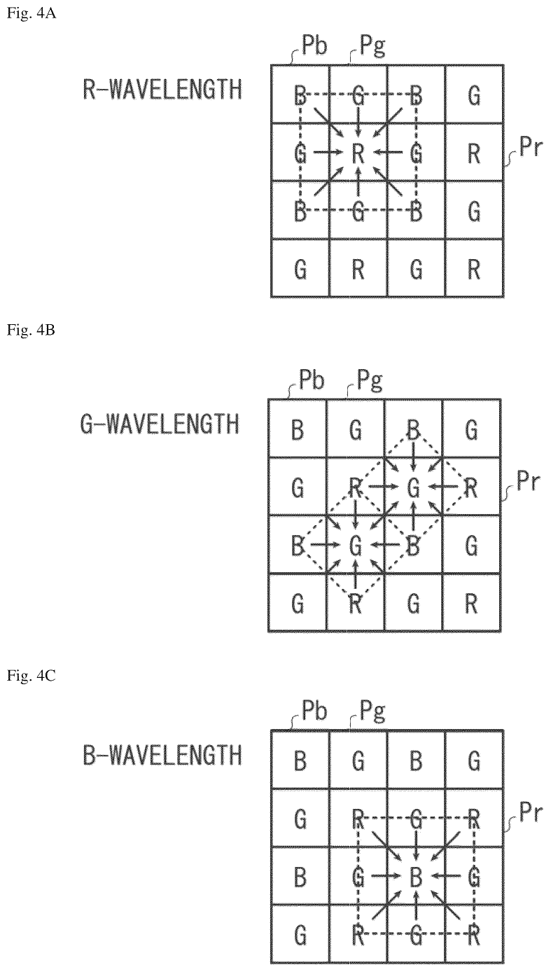

FIG. 3 is a diagram illustrating an example of a cross-sectional configuration of the imaging device according to the embodiment. FIGS. 4A to 4C are each a diagram illustrating an example of a planar configuration of the imaging device according to the embodiment. As illustrated in FIG. 3, the imaging device 1 has a configuration in which, for example, the light-guiding section 50, a transparent layer 20 (a transparent layer 20a and a transparent layer 20b in FIG. 3), the color filter 25, a light-receiving section 10, and a multilayer wiring layer 90 are stacked in the Z-axis direction. As in the example illustrated in FIG. 3, the pixel P includes a photoelectric conversion section 12.

The light-receiving section 10 illustrated in FIG. 3 includes a semiconductor substrate 11 having a first surface 11S1 and a second surface 11S2 that are opposed to each other. The semiconductor substrate 11 is configured by, for example, a silicon substrate. The color filter 25, the light-guiding section 50, and the like, are provided on the first surface 11S1 of the semiconductor substrate 11. The multilayer wiring layer 90 is provided on the second surface 11S2 of the semiconductor substrate 11. The light-guiding section 50, the color filter 25, and the like, are provided on a side on which light from the optical system is incident, and the multilayer wiring layer 90 is provided on a side opposite to the side on which light is incident. The imaging device 1 is a so-called back-illuminated imaging device.

In the light-receiving section 10, a plurality of photoelectric conversion sections 12 is provided between the first surface 11S1 and the second surface 11S2 of the semi-conductor substrate 11. For example, the plurality of photoelectric conversion sections 12 is embedded and formed in the semiconductor substrate 11. The photoelectric conversion section 12 is configured to be able to generate an electrical charge by photoelectric conversion. The photoelectric conversion section 12 is a photodiode (PD) and converts incoming light into an electrical charge. The photoelectric conversion section 12 performs photoelectric conversion to generate the electrical charge corresponding to a received light amount.

The multilayer wiring layer 90 has a configuration in which, for example, a plurality of wiring lines is stacked with an interlayer insulating layer (interlayer insulating film) interposed therebetween. The wiring layer of the multilayer wiring layer 90 is formed using, for example, aluminum (Al), copper (Cu), or the like. The wiring layer may be formed using polysilicon (Poly-Si). As an example, the interlayer insulating layer is formed using silicon oxide (SiOx), silicon nitride (SiNx), silicon oxynitride (SiOxNy), or the like.

The semiconductor substrate 11 and the multilayer wiring layer 90 are provided with a readout circuit (unillustrated) configured to be able to output a pixel signal based on the electrical charge generated by the photoelectric conversion section 12. It is to be noted that the pixel drive section 111, the signal processing section 112, the control section 113, and the processing section 114 described above may be formed in a substrate different from the semiconductor substrate 11 or in the semiconductor substrate 11 and the multilayer wiring layer 90.

The readout circuit of the pixel P includes, for example, a transfer transistor, a floating diffusion (FD), a reset transistor, an amplification transistor, and the like. The readout circuit is configured to be able to read a pixel signal based on the electrical charge converted by the photoelectric conversion section 12 to the signal line L2 which is the vertical signal line described above.

The pixel drive section 111 (see FIG. 1) controls the readout circuit of each of the pixels P to thereby cause each of the pixels P to output a pixel signal to the signal line L2. The pixel drive section 111 can perform control to read the pixel signal of each of the pixels P to the signal line L2. It is to be noted that the pixel drive section 111 and the control section 113 may also be collectively referred to as the pixel control section.

The transparent layer 20 (transparent layer 20a and transparent layer 20b in FIG. 3) transmits light, and is formed by, for example, a low refractive index material such as silicon oxide (SiOx) or silicon nitride (SiNx). The transparent layer 20a and the transparent layer 20b may each be configured by another transparent material that transmits light.

The light-guiding section 50 includes structures 30 and is configured to guide incident light to the light-receiving section 10. Light from a subject to be measured is incident on the light-guiding section 50. The structures 30 are fine (minute) structures and include a first section 31 and a second section 32 provided below the first section 31, as illustrated in FIG. 3. The first section 31 is in contact with the second section 32. It is to be noted that, as used herein, the phrase “in contact” includes a case of being in direct contact as well as a case of being in contact, with a natural oxide film or the like interposed therebetween. The phrase “the first section 31 is in contact with the second section 32” includes a case where the natural oxide film is interposed therebetween as well as a case where the first section 31 is in contact with the second section 32 with a thin natural oxide film interposed therebetween. As in the example illustrated in FIG. 3, the first section 31 and the second section 32 are provided to be in contact with each other.

As in the example illustrated in FIG. 3, the first section 31 and the second section 32 are provided continuously. In addition, the structures include a material (a first member 41) provided next to the first section 31 and a material (a second member 42) provided next to the second section 32. The light-guiding section 50 has a stacked structure in which the first member 41 and the second member 42 are stacked.

The first section 31 and the second section 32 of the structures 30 are each a fine structure having a size equal to or less than a predetermined wavelength of incoming light, and has, for example, a size equal to or less than a wavelength of visible light. It is to be noted that the first section 31 and the second section 32 may each have a size equal to or less than a wavelength of infrared light.

The light-guiding section 50 is an optical element (optical member) that guides (propagates) light. The light-guiding section 50 (light-guiding member) utilizes the structure 30, which is a fine structure, to propagate light to the photoelectric conversion section 12. As described later, the light-guiding section 50 according to the present embodiment also serves as a light-dispersing section (light-disperser) and is configured to disperse incoming light. The light-guiding section 50 is provided for each pixel P or for each plurality of pixels P.

The structures 30 are, for example, columnar (pillar-shaped) structures, as illustrated in FIG. 3. As schematically illustrated in FIG. 3, a plurality of structures 30 are arranged side by side in the right-left direction (X-axis direction) on the plane. In each of the pixels P of the imaging device 1, the plurality of structures 30 can be arranged at an interval equal to or less than a predetermined wavelength of incident light, e.g., at an interval equal to or less than a wavelength of visible light.

Respective first sections 31 of a plurality of structures 30 are arranged side by side in the right-left direction (X-axis direction) with the first member 41 interposed therebetween. It can also be said that the first section 31 is provided in the first member 41 and is arranged to partially replace the first member 41. Respective second sections 32 of the plurality of structures 30 are arranged side by side in the right-left direction (X-axis direction) with the second member 42 interposed therebetween. It can also be said that the second section 32 is provided in the second member 42 and is arranged to partially replace the second member 42.

The structures 30 have a refractive index different from a refractive index of a surrounding material. In the example illustrated in FIG. 3, the structures 30 have a refractive index different from refractive indexes of the first member 41 and the second member 42 which are materials around the structure 30. The first section 31 of the structures 30 has a refractive index different from the refractive index of the first member 41. In addition, the second section 32 of the structures 30 has a refractive index different from the refractive index of the second member 42.

For example, the first section 31 of the structures 30 may have a refractive index higher than the refractive index of the first member 41. The second member 32 of the structures 30 may have a refractive index higher than the refractive index of the second member 42. The structures 30 can be configured by a material having a refractive index higher than the refractive index of the first member 41 and the refractive index of the second member 42.

In addition, for example, the first section 31 may have a refractive index lower than the refractive index of the first member 41. The second section 32 may have a refractive index lower than the refractive index of the second member 42. The structures 30 can be configured by a material having a refractive index lower than the refractive index of the first member 41 and the refractive index of the second member 42.

As an example, the structures 30 are formed using silicon, a silicon compound (silicon nitride, silicon carbide, silicon oxynitride, etc.), or the like. In addition, the structures 30 may be configured using amorphous silicon (a-Si), polysilicon, germanium (Ge), or the like.

The structures 30 may be configured by a simple substance such as oxide, nitride, oxynitride, or composite of titanium, hafnium, zirconium, tantalum, aluminum, niobium, indium, and the like. In addition, the structures 30 may be configured from an organic matter such as siloxane. For example, the structures 30 may be configured using a siloxane-based resin, a styrene-based resin, an acrylic-based resin, or the like.

The first member 41 and the second member 42 may each be configured by a simple substance such as oxide, nitride, oxynitride, or composite of silicon, titanium, hafnium, zirconium, tantalum, aluminum, niobium, indium, and the like. In addition, the first member 41 and the second member 42 may each be configured from an organic matter such as siloxane.

For example, the first member 41 and the second member 42 may each be configured by a siloxane-based resin, a styrene-based resin, an acrylic-based resin, or the like. The first member 41 and the second member 42 may be configured using different materials or may be configured using the same type of material. It is to be noted that the structures 30, the first member 41, and the second member 42 may be partially configured using air (e.g., an air gap).

The light-guiding section 50 causes a phase delay in incoming light due to the difference between the refractive index of the structures 30 and the refractive index of the surrounding material, thus making it possible to exert an influence on a wave front. The light-guiding section 50 provides different phase delay amounts in response to a wavelength of the light to thereby adjust a direction in which light propagates, thus making it possible to split the incident light into light beams of respective wavelengths.

A size, shape, refractive index, and the like, of each of the structures 30 are determined to allow light of each of the wavelengths included in the incident light to travel in a desired direction. In the example illustrated in FIG. 3, the size, shape, refractive index, and the like, of each of the first section 31 and the second section 32 of the structures 30 can be adjusted.

The light-guiding section 50 (light-dispenser) is a light-dispersing element that is able to disperse light by utilizing a metamaterial (metasurface) technology, and can also be referred to as a splitter (color splitter). The imaging device 1 can also be referred to as having a color splitter structure.

The direction in which the light-guiding section 50 propagates light of each wavelength is adjusted by the materials (optical constants) for the structures 30, the first member 41, the second member 42, and the like, and the shape, height, arrangement interval (gap), and the like, of the structures 30. The light-guiding section 50 can also be referred to as a region (light-dispersing region) where the structures 30 disperse the incident light.

The light-guiding section 50 is a light-dispersing section configured to disperse the incident light. The light-guiding section 50 provides light beams of a plurality of wavelengths, e.g., light beams of a first wavelength to a third wavelength with respective different phase delays. This enables the imaging device 1 to disperse the light incident on the light-guiding section 50 into the light of the first wavelength (e.g., light of a red wavelength), light of a second wavelength (e.g., light of a green wavelength), and the light of the third wavelength (e.g., light of a blue wavelength).

The light-guiding section 50 of the pixel Pg is configured to propagate incoming light having a wavelength of green (G) light to the color filter 25 and the photoelectric conversion section 12 of the pixel Pg, and to propagate incoming light having a wavelength of red (R) light to the color filter 25 and the photoelectric conversion section 12 of the pixel Pr. The light-guiding section 50 of the pixel Pg also splits incident light to guide the incident light having a wavelength of red light towards the pixel Pr.

In addition, the light-guiding section 50 of the pixel Pg is configured to propagate incoming light having a wavelength of blue (B) light to the color filter 25 and the photoelectric conversion section 12 of the pixel Pb. The light-guiding section 50 of the pixel Pg also splits incident light to guide the incident light having a wavelength of blue light towards the pixel Pb.

The light-guiding section 50 of the pixel Pr is configured to propagate incoming light having a wavelength of red (R) light to the color filter 25 and the photoelectric conversion section 12 of the pixel Pr, and to propagate incoming light having a wavelength of green (G) light to the color filter 25 and the photoelectric conversion section 12 of the pixel Pg. The light-guiding section 50 of the pixel Pr also splits incident light to guide the incident light having a wavelength of green light towards the pixel Pg.

In addition, the light-guiding section 50 of the pixel Pr is configured to propagate incoming light having a wavelength of blue (B) light to the color filter 25 and the photoelectric conversion section 12 of the pixel Pb. The light-guiding section 50 of the pixel Pr also splits incident light to guide the incident light having a wavelength of blue light towards the pixel Pb.

The light-guiding section 50 of the pixel Pb is configured to propagate incoming light having a wavelength of blue (B) to the color filter 25 and the photoelectric conversion section 12 of the pixel Pb, and to propagate incoming light having a wavelength of green (G) to the color filter 25 and the photoelectric conversion section 12 of the pixel Pg. The light-guiding section 50 of the pixel Pb also splits incident light to guide the incident light having a wavelength of green light towards the pixel Pg.

In addition, the light-guiding section 50 of the pixel Pb is configured to propagate incoming light having a wavelength of red (R) light to the color filter 25 and the photoelectric conversion section 12 of the pixel Pr. The light-guiding section 50 of the pixel Pb also splits incident light to guide the incident light having a wavelength of red light towards the pixel Pr.

Thus, as schematically indicated by arrows in FIG. 4A, a plurality of pixels surrounding the pixel Pr guides incident light having a wavelength of red light towards the pixel Pr. It is possible to condense incident light having a wavelength of the red light on the pixel Pr and incident light having a wavelength of red light on each of surrounding pixels of the pixel Pr on the color filter 25 and the photoelectric conversion section 12 of the pixel Pr. The photoelectric conversion section 12 of the pixel Pr efficiently receives incident light having a wavelength of red light to perform photoelectric conversion, thus making it possible to generate an electrical charge corresponding to a received light amount.

As schematically indicated by arrows in FIG. 4B, a plurality of pixels surrounding the pixel Pg guides incident light having a wavelength of green light towards the pixel Pg. It is possible to condense incident light having a wavelength of green light on the pixel Pg and incident light having a wavelength of green light on each of surrounding pixels of the pixel Pg on the color filter 25 and the photoelectric conversion section 12 of the pixel Pg. The photoelectric conversion section 12 of the pixel Pg efficiently receives incident light having a wavelength of green light to perform photoelectric conversion, thus making it possible to generate an electrical charge corresponding to a received light amount.

In addition, as schematically indicated by arrows in FIG. 4C, a plurality of pixels surrounding the pixel Pb guides incident light having a wavelength of blue light towards the pixel Pb. It is possible to condense incident light having a wavelength of blue light on the pixel Pb and incident light having a wavelength of blue light on each of surrounding pixels of the pixel Pb on the color filter 25 and the photoelectric conversion section 12 of the pixel Pb. The photoelectric conversion section 12 of the pixel Pb efficiently receives incident light having a wavelength of blue light to perform photoelectric conversion, thus making it possible to generate an electrical charge corresponding to a received light amount.

In this manner, the imaging device 1 is able to take more light effectively into the pixel P, thus making it possible to improve quantum efficiency (QE). It is to be noted that the structures 30 of the respective light-guiding sections 50 of the above-described pixel Pr, pixel Pg, and pixel Pb can be formed to have different sizes, shapes, and the like, for example.

In the imaging device 1 according to the present embodiment, as described above, the light-guiding section 50 is formed by using the layer in which the first section 31 and the first member 41 are provided and the layer in which the second section 32 and the second member 42 are provided. Allowing the light-guiding section 50 to have a stacked structure makes it possible to finely control the shape of the structures 30. This enables the imaging device 1 to have a reduced height, thus making it possible to effectively suppress deterioration in spectral characteristics in a case of oblique incident light. It is also possible to form the light-guiding section 50 having a topological three-dimensional (3D) shape.

When the imaging device 1 is manufactured, the first member 41 and the second member 42 serve as etching stopper films, thus enabling processing controllability of the structures 30 to be improved. This also makes it possible to process the structures 30 into non-tapered shapes (e.g., shapes without an inclined part). It is possible to process the cross-sectional structures designed.

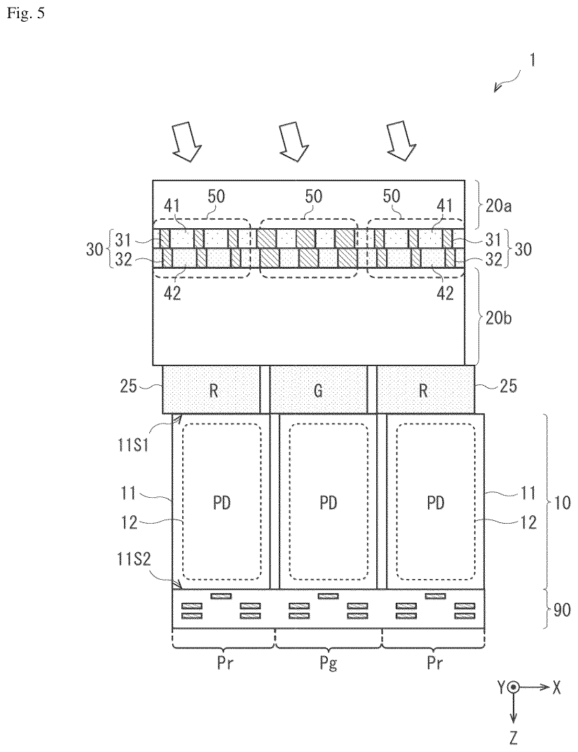

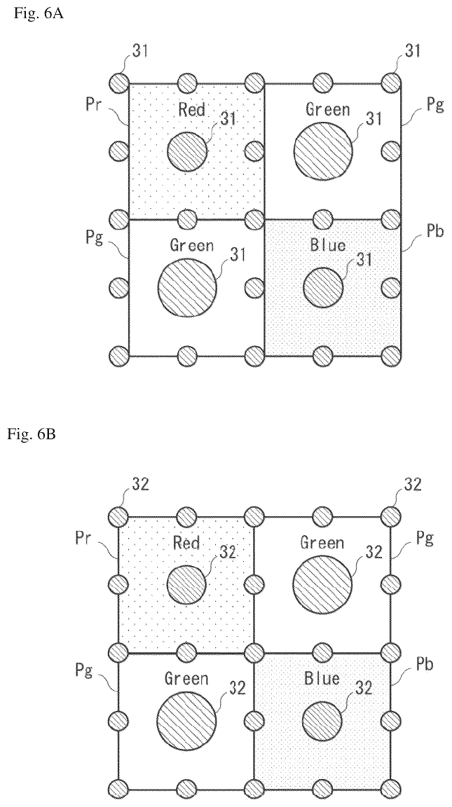

FIG. 5 illustrates an example of a cross-sectional configuration of a light-guiding section in a region where a distance from the center of the pixel section 100 (pixel array) of the imaging device 1, i.e., an image height is high. FIGS. 6A and 6B of FIG. 6 each illustrate, respectively, examples of planar configurations of the first section 31 of the light-guiding section 50 and the second section 32 of the light-guiding section 50 where the image height is high.

Light from an optical lens is incident substantially perpendicularly on the middle part of the pixel section 100 of the imaging device 1. Meanwhile, as in the example indicated by white arrows in FIG. 5, oblique incident light is provided on a peripheral region positioned outward from the middle part, i.e., on a region distant from the middle of the pixel section 100. Therefore, in the imaging device 1, as illustrated in FIGS. 5 and 6A and 6B, positions of the first section 31 and the second section 32 of the light-guiding section 50, the color filter 25, the photoelectric conversion section 12, or the like in each of the pixels P are configured to differ depending on the distance from the center of the pixel section 100, i.e., the image height.

As illustrated in FIGS. 5 and 6A and 6B, the first section 31 of the light-guiding section 50 of the pixel P is arranged to be shifted towards the middle of the pixel section 100 with respect to the second section 32 of the light-guiding section 50 of the pixel P. The second section 32 of the light-guiding section 50 of the pixel P can also be referred to as being shifted towards the end of the pixel section 100 with respect to the first section 31 of the light-guiding section 50 of the pixel P.

In the example illustrated in FIG. 5, the first section 31 of the light-guiding section 50 is provided to be shifted in a left direction on the plane with respect to the second section 32 of the light-guiding section 50. The second section 32 of the light-guiding section 50 can also be referred to as being shifted in a right direction on the plane with respect to the first section 31 of the light-guiding section 50.

It is to be noted that, in the middle region of the pixel section 100 (pixel array), the pixels P are configured, for example, as illustrated in FIGS. 2 and 3 described above. In the pixel P at the middle of the pixel section 100, as illustrated in FIG. 3, respective center positions of the first section 31 and the second section 32 of the light-guiding section 50 are substantially coincident with each other. In addition, respective center positions of the color filter 25 and the photoelectric conversion section 12 are substantially coincident with each other.

Thus, in the imaging device 1, respective positions of the first section 31, the second section 32, and the like, of the light-guiding section 50 are adjusted depending on the image height, thus enabling pupil corrections to be appropriately performed. It is possible to suppress a decrease in an amount of light incident on the photoelectric conversion section 12, and thus to prevent a decrease in sensitivity to the incident light. Even in a case of oblique incident light, it is possible to appropriately propagate incoming light to the photoelectric conversion section 12.

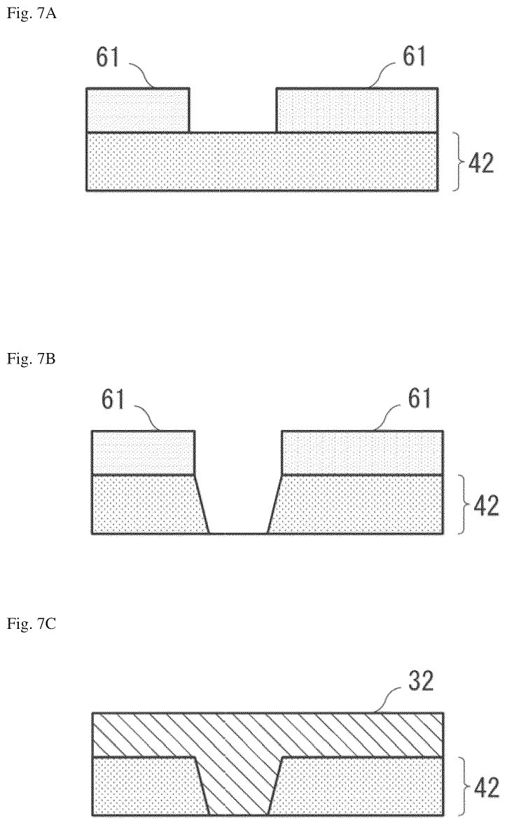

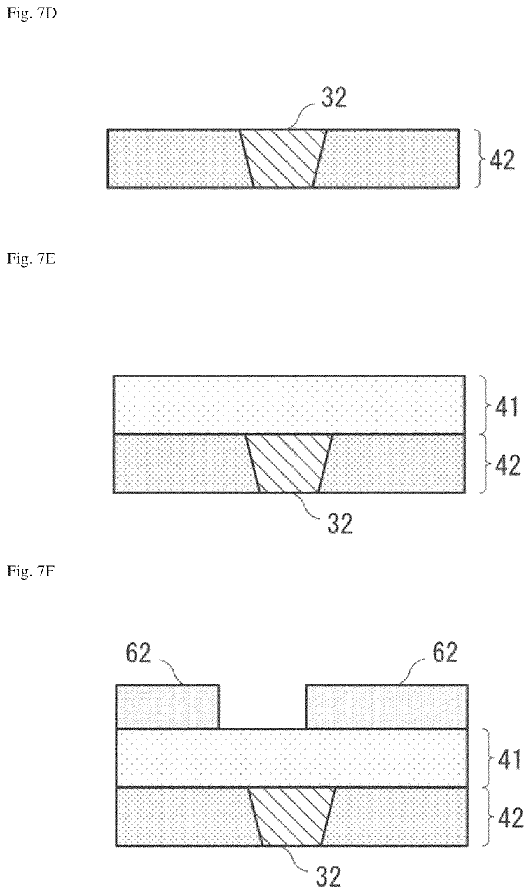

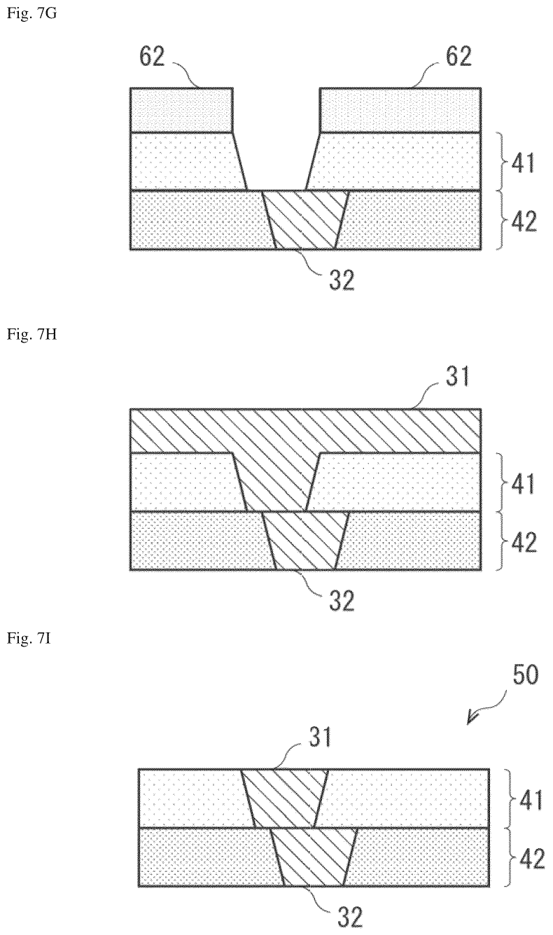

FIGS. 7A to 7I are each a diagram illustrating an example of a method of manufacturing a light-guiding section of an imaging device according to an embodiment.

First, as illustrated in FIG. 7A, a resist film 61 is formed on the second member 42 by lithography and etching. In addition, as illustrated in FIG. 7B, a portion of the second member 42 is removed by dry etching. Then, as illustrated in FIG. 7C, a titanium oxide film (TiO film) is formed as the second section 32 of the structure 30.

Next, as illustrated in FIG. 7D, an excess titanium oxide film is removed by Chemical-Mechanical Polishing (CMP) processing. In addition, as illustrated in FIG. 7E, the first member 41 is formed on the second member 42. Then, as illustrated in FIG. 7F, a resist film 62 is formed as a film by lithography and etching.

Next, as illustrated in FIG. 7G, a portion of the first member 41 is removed by dry etching. In addition, as illustrated in FIG. 7H, a titanium oxide film (TiO film) is formed, as the first section 31 of the structure 30, on the second member 42. Then, as illustrated in FIG. 7I, an excess titanium oxide film is removed by CMP processing. The above-described manufacturing method enables the light-guiding section 50 illustrated in FIG. 3, or the like, to be manufactured. It is to be noted that the above-described manufacturing method is merely exemplary, and other manufacturing methods may be employed.

### Workings and Effects

The photodetector according to the present embodiment includes a light-guiding section (light-guide 50) including a structure (structure 30) including a first section (first section 31) having a size equal to or less than a wavelength of incident light and a second section (second section 32) provided below the first section. A first material (first member 41) is provided next to the first section and has a refractive index different from a refractive index of the structure and a second material (second member 42) is provided next to the second section and has a refractive index different from the refractive index of the structure. A first photoelectric conversion section (photoelectric converter 12) photoelectrically converts light incident via the light-guiding section. The first section is in contact with the second section.

The photodetector (imaging device 1) according to the present embodiment is provided with the light-guiding section 50 including the structure 30 including the first section 31 and the second section 32, and the first member 41 and the second member 42. Allowing the light-guiding section 50 to have a stacked structure enables the shape of the structure 30 to be controlled, thus making it possible to suppress a decrease in sensitivity to oblique incident light. It is possible to implement a photodetector having favorable detection performance.

In the present embodiment, the first section and the second section of the structure 30 are provided to be in contact with each other. It is therefore possible to improve light controllability. In addition, as compared with a case where the first section and the second section are provided separately, it is possible to decrease the number of steps in the manufacturing steps, thus making it possible to prevent an increase in the manufacturing costs of the imaging device 1.

Next, descriptions are given of modification examples of the present disclosure. Hereinafter, components similar to those of the foregoing embodiments are denoted by the same reference numerals, and descriptions thereof are omitted as appropriate.

### 2. Modification Examples

### 2-1. Modification Example 1

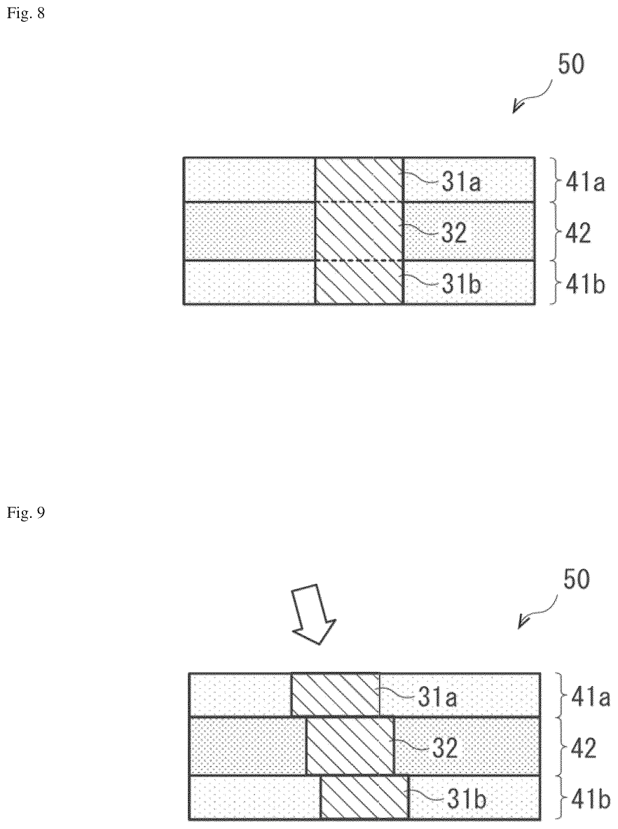

FIG. 8 is a diagram illustrating an example of a cross-sectional configuration of a light-guiding section of an imaging device according to Modification Example 1 of the present disclosure. The light-guiding section 50 may be configured using a plurality of first sections 31a second section 32, a plurality of first members 41 and a second member 42. For example, as in the example illustrated in FIG. 8, the light-guiding section 50 may have a configuration in which a layer provided with a first section 31a and a first member 41a, a layer provided with the second section 32 and the second member 42, and a layer provided with a first section 31b and a first member 41b are stacked.

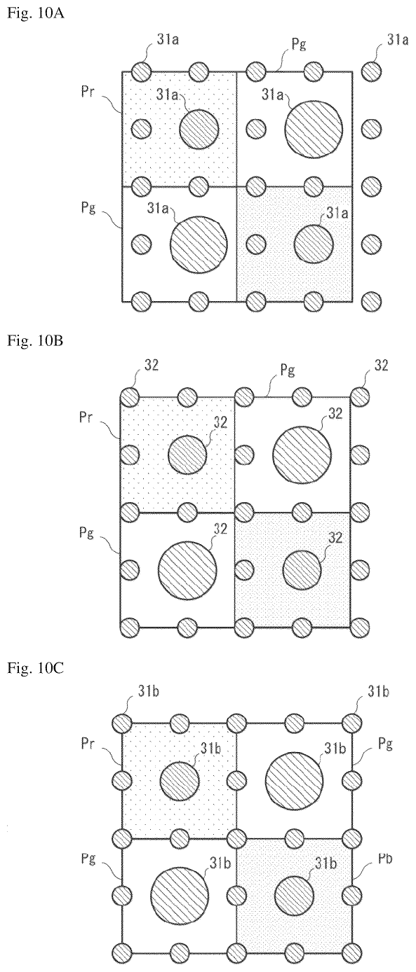

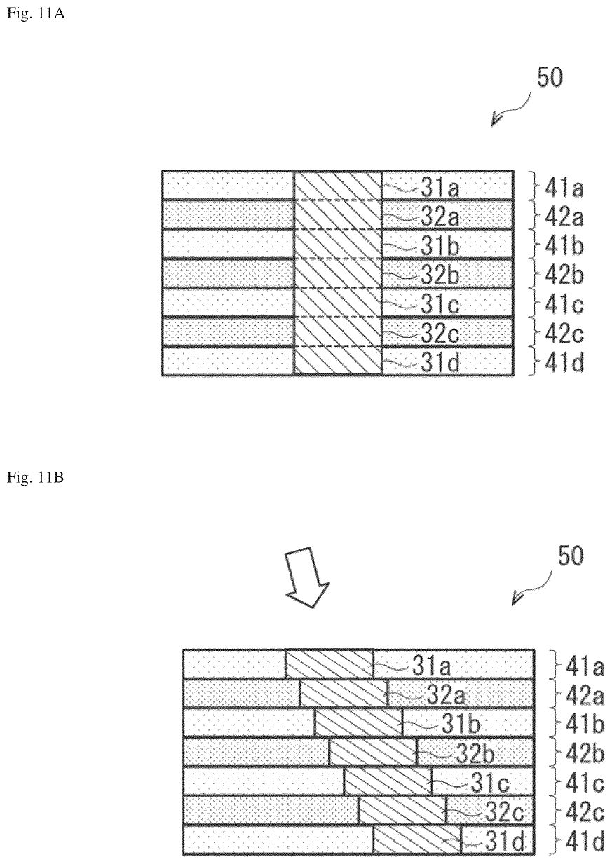

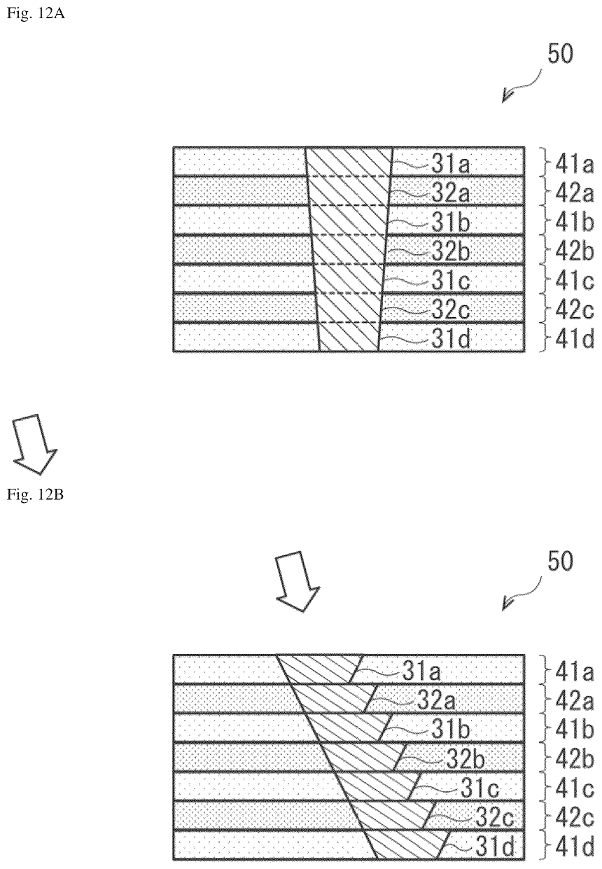

FIG. 9 illustrates an example of a cross-sectional configuration of the light-guiding section 50 of the pixel P where the image height is high. In addition, FIGS. 10A-10(C) illustrate examples of planar configurations of the first section 31a of the light-guiding section 50 where the image height is high, the second section 32 of the light-guiding section 50, and the first section 31b of the light-guiding section 50b.

As in the example illustrated in FIGS. 9 and 10A-10C, the first section 31a, the second section 32, and the first section 31b may be arranged to be shifted depending on the image height. The center position of the first section 31a, the center position of the second section 32, and the center position of the first section 31b differ from one another, in a manner corresponding to a direction of the incident from a subject. In the present modification example, it is possible for the three layers of the light-guiding section 50 to appropriately guide oblique incident light.

As illustrated in FIG. 11A, the light-guiding section 50 may be configured using first sections 31a to 31d, second sections 32a to 32c, first members 41a to 41d, and second members 42a to 42c. In addition, as illustrated in FIG. 11B, in a region distant from the middle of the pixel section 100, each of the first sections 31a to 31d and the second sections 32a to 32c may be arranged to be shifted in a manner corresponding to the direction of the incident light. It is to be noted that the first sections 31a to 31d and the second sections 32a to 32c of the structures 30 may have a tapered shape, as illustrated in FIGS. 12A and/or 12B.

### 2-2. Modification Example 2

A plurality of sections constituting the structures 30, e.g., the first section 31 and the second section 32 may have different sizes (heights (thicknesses), widths, etc.). In addition, a material around the structures 30, e.g., the first member 41 and the second member 42 may have different sizes (thicknesses, widths, etc.).

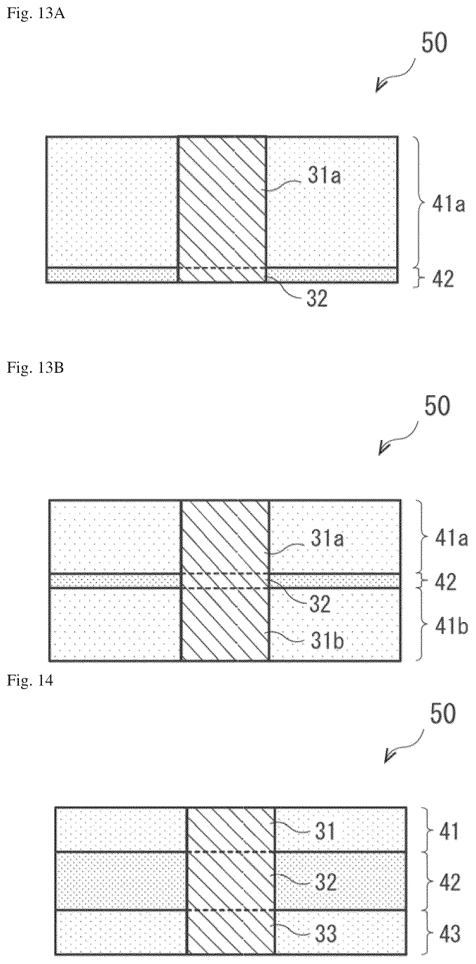

FIGS. 13A and 13B are each a diagram illustrating an example of a cross-sectional configuration of a light-guiding section of an imaging device according to Modification Example 2. As illustrated in FIGS. 13A and/or 13B, the first section 31 and the second section 32 may have different sizes. In the example illustrated in FIG. 13A, a size of the second section 32 is smaller than a size of the first section 31a. In addition, in the example illustrated in FIG. 13B, the size of the second section 32 is smaller than a size of each of the first section 31a and the first section 31b.

FIG. 14 is a diagram illustrating another example of the cross-sectional configuration of the light-guiding section of the imaging device according to Modification Example 2. As illustrated in FIG. 14, the light-guiding section 50 may include a third section 33 provided below and in contact with the second section 32, and a third member 43 provided next to the third section 33. The second section 32 and the third section 33 are in contact with each other. Here, the phrase “the second section 32 and the third section 33 are in contact with each other” includes a case where a natural oxide film is interposed therebetween and includes a case where the second section 32 is in contact with the third section 33 with a thin natural oxide film interposed therebetween. As in the example illustrated in FIG. 14, the second section 32 and the third section 33 are provided to be in contact with each other.

The first section 31, the second section 32, and the third section 33 may have different sizes (thicknesses, widths, etc.). Depending on the image height, the first section 31, the second section 32, and the third section 33 may be arranged to be shifted. The first member 41, the second member 42, and the third member 43 can be configured using different materials, for example.

### 2-3. Modification Example 3

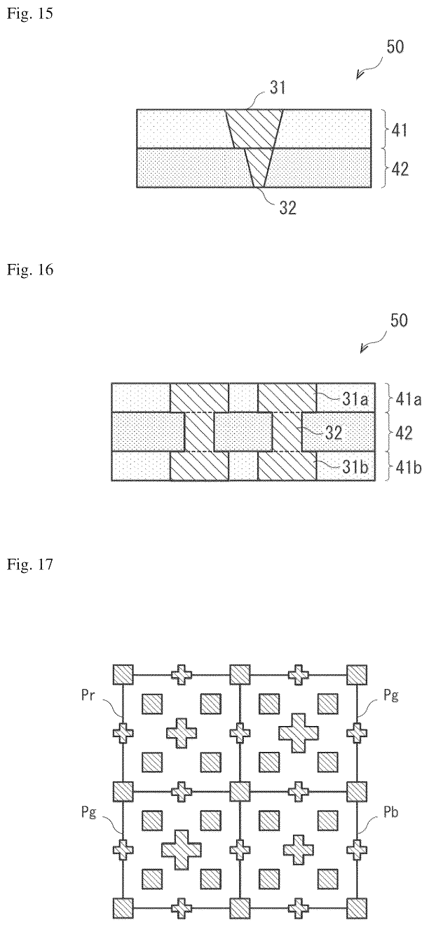

FIG. 15 is a diagram illustrating an example of a cross-sectional configuration of a light-guiding section of an imaging device according to Modification Example 3. As in the example illustrated in FIGS. 15 and/or 16, the first section 31 and the second section 32 may have different widths. The first section 31 and the second section 32 can be formed to have different sizes, shapes, and the like, for example. In this case, it is possible to effectively suppress deterioration in spectral characteristics in the case of oblique incident light.

The first sections 31a and 31b, and the second section 32 may each have a cross shape, a quadrangular shape, or the like, as in the example illustrated in FIG. 17. The shape of the structure 30 is appropriately modifiable, and may be, for example, a quadrangular shape in a plan view. The shape of the structures 30 may be a polygon, an ellipse, a cross, or another shape.

### 2-4. Modification Example 4

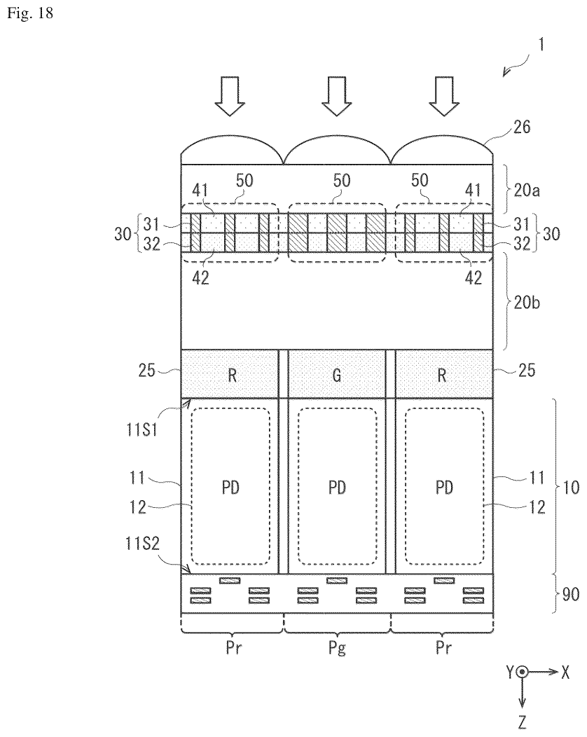

FIG. 18 is a diagram illustrating an example of a cross-sectional configuration of an imaging device according to Modification Example 4. As illustrated in FIG. 18, the imaging device 1 may include a lens section 26. The lens section 26 guides incident light from above to the light-guiding section 50. The lens section 26 is an optical member also called an on-chip lens. The lens section 26 is provided above the light-guiding section 50, for example, for each pixel P or for each plurality of pixels P. Light from a subject is incident on the lens section 26 via an optical system such as an imaging lens. The photoelectric conversion section 12 can photoelectrically convert incident light via the lens section 26, the light-guiding section 50, and the color filter 25.

It is to be noted that, instead of or in addition to the color filter 25, a light-guiding section configured using a structure may be provided above the photoelectric conversion section 12. Similarly, to the structures 30 of the light-guiding section 50, for example, these structures are columnar fine structures. It is to be noted that the shape of the structures is appropriately modifiable and may be a polygon or another shape.

### 3. Application Example

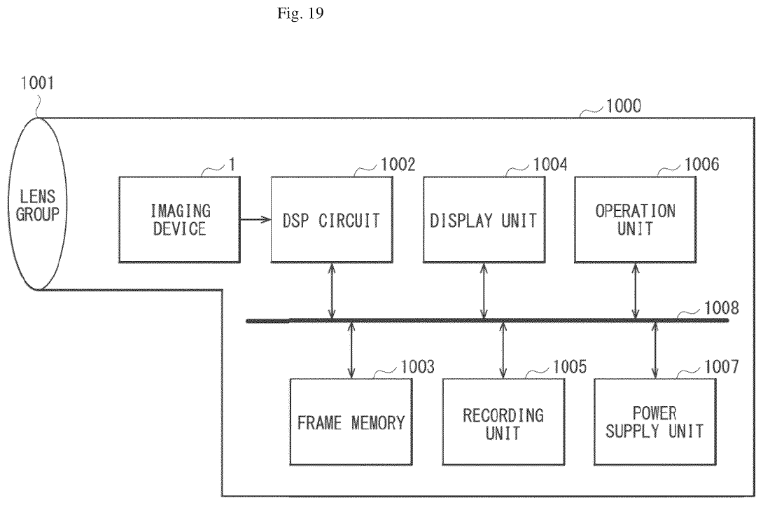

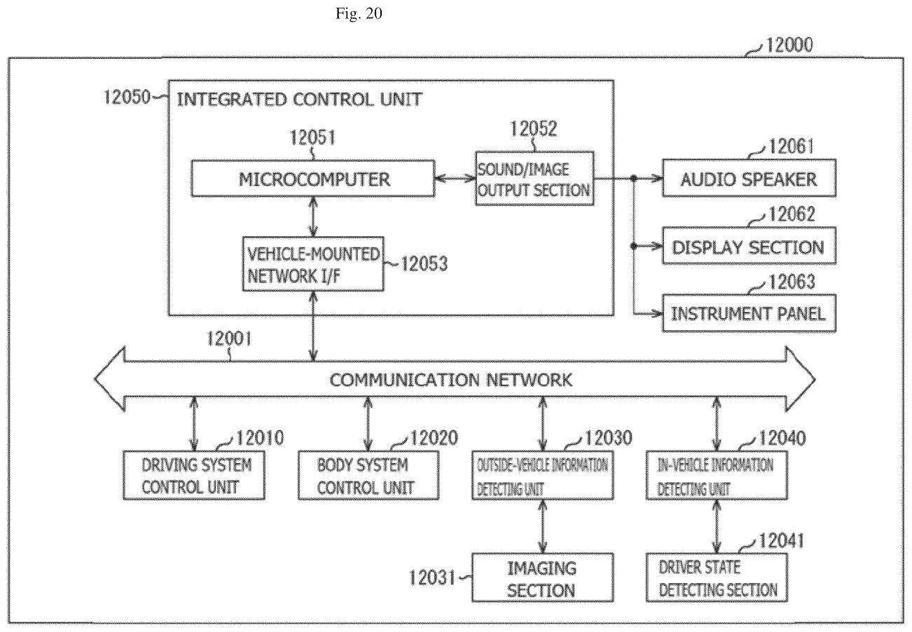

The above-described imaging device 1 or the like is applicable, for example, in any type of electronic apparatus having an imaging function including a camera system such as a digital still camera or a video camera, a mobile phone, and the like. FIG. 19 illustrates a schematic configuration of an electronic apparatus 1000.

The electronic apparatus 1000 includes, for example, a lens group 1001, the imaging device 1, a Digital Signal Processor (DSP) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject and forms an image on an imaging surface of the imaging device 1. The imaging device 1 converts the amount of incident light formed as an image on the imaging surface by the lens group 1001 into electrical signals on a pixel-by-pixel basis and supplies the DSP circuit 1002 with the electrical signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic Electro Luminescence (EL) panel, and records image data of a moving image or a still image captured by the imaging device 1 on a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, a robot, or the like.

FIG. 20 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches, can be input to the body system control unit 12020. The body system control unit 12020 receives these input radio waves or signals, and controls a door lock device, the power window device, the lamps, or the like, of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 instructs the imaging section 12031 to provide an image of the outside of the vehicle, and then receives the image from the imaging section 12031. Based on the received image, the outside-vehicle information detecting unit 12030 processes the received image to detect objects such as a human, a vehicle, an obstacle, a sign, a character on a road surface, or the like, or process the received image to detected distances from objects.

The imaging section 12031 is an optical sensor that receives light, and outputs an electrical signal corresponding to a received amount of light. The imaging section 12031 can output the electrical signal as an image or can output the electrical signal as information about a measured distance. In addition, the light received by the imaging section 12031 may be visible light or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. Based on the detection information input from the driver state detecting section 12041, the in-vehicle information detecting unit 12040 may calculate a degree of fatigue of the driver or a degree of concentration of the driver or may determine whether the driver is dozing off.

The microcomputer 12051 can calculate a control target value for the driving force generating device, the steering mechanism, or the braking device based on the information about the inside or outside of the vehicle obtained by the outside-vehicle information detecting unit 12030 or the in-vehicle information detecting unit 12040, and can output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, (e.g., operating the vehicle without input from the driver, or the like), by controlling the driving force generating device, the steering mechanism, the braking device, or the like based on the information about the outside or inside of the vehicle obtained by the outside-vehicle information detecting unit 12030 or the in-vehicle information detecting unit 12040.

In addition, the microcomputer 12051 can output a control command to the body system control unit 12020 based on the information about the outside of the vehicle which information is obtained by the outside-vehicle information detecting unit 12030. For example, the microcomputer 12051 can perform cooperative control intended to prevent a glare by controlling the headlamp to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

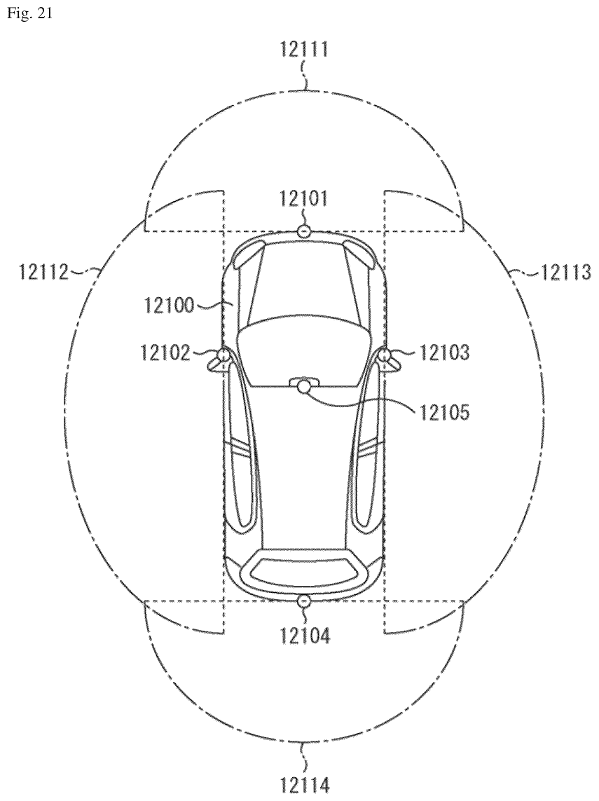

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle, obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door, obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) based on the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance and perform automatic brake control (including following stop control), automatic acceleration control (including following start control), or the like. It is thus possible to perform cooperative control intended for automated driving that allows the vehicle to operate in an automated manner without depending on input from the driver, or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects based on the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062 and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether there is a pedestrian in images of the imaging sections 12101 to 12104. Such recognition of a pedestrian is, for example, performed by a procedure of extracting characteristic points in the images of the imaging sections 12101 to 12104 as infrared cameras and a procedure of determining whether it is the pedestrian by performing pattern matching processing on a series of characteristic points representing the contour of the object. When the microcomputer 12051 determines that there is a pedestrian in the images of the imaging sections 12101 to 12104, and thus recognizes the pedestrian, the sound/image output section 12052 controls the display section 12062 so that a square contour line for emphasis is displayed to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1, or the like, can be applied to the imaging section 12031. Applying the technology according to an embodiment of the present disclosure to the imaging section 12031 enables one to obtain images having high definition, thus making it possible to perform highly accurate control utilizing the image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

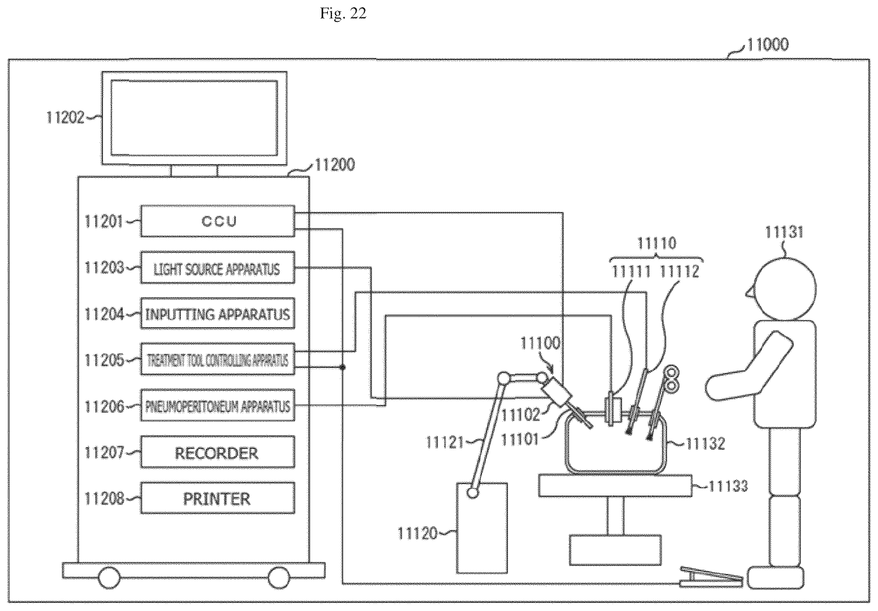

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted and includes as a rigid endoscope having the lens barrel 11101 of the hard type. However, the endoscope 11100 may otherwise be included as a flexible endoscope having the lens barrel 11101 of the flexible type.

The lens barrel 11101 has at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pick-up element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as raw data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (e.g., demosaic processing).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user may input an instruction, or the like, to change an image pick-up condition (type of irradiation light, magnification, focal distance or the like) by the endoscope 11100.

A treatment tool controlling apparatus 11205 controls driving of the energy device 11112 for cautery or incision of a tissue, sealing of a blood vessel, or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image, or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustments to the white balance of a picked-up image can be performed by the light source apparatus 11203. Further, in this case, if laser beams from the respective RGB laser light sources are irradiated time-divisionally on an observation target and driving of the image pick-up elements of the camera head 11102 are controlled in a synchronous manner with the irradiation timings. Then images individually corresponding to the R, G and B colors can be also picked up time-divisionally. According to this method, a color image can be obtained even if color filters are not provided for the image pick-up element.

Further, the light source apparatus 11203 may be controlled such that the intensity of light to be output is changed for each predetermined time. By controlling the driving of the image pick-up element of the camera head 11102 in synchronism with the timing of the change of the intensity of light to acquire images time-divisionally and synthesizing the images, an image of a high dynamic range, free from underexposed blocked up shadows and overexposed highlights, can be created.

Further, the light source apparatus 11203 may be configured to supply light of a pre-determined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observations, it is possible to perform observations of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

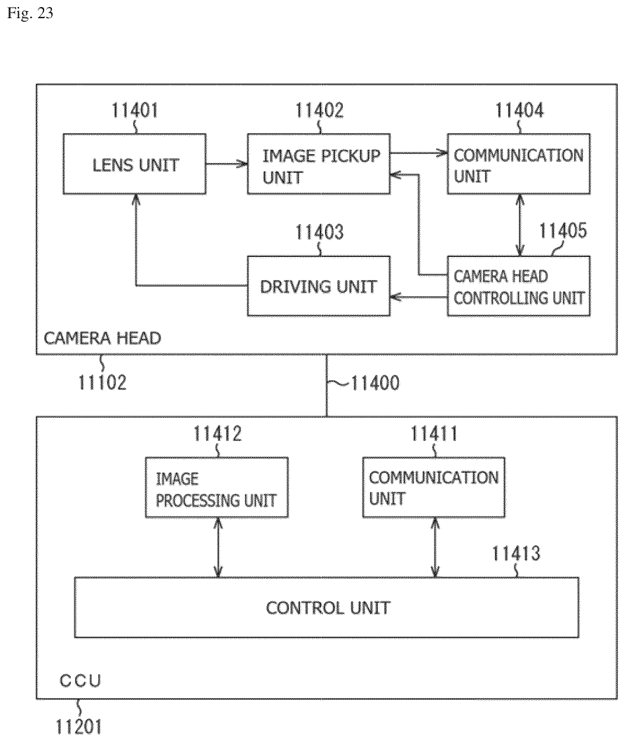

FIG. 23 is a block diagram depicting an example of a functional configuration of the camera head 11102 and the CCU 11201 depicted in FIG. 22.

The camera head 11102 includes a lens unit 11401, an image pick-up unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pick-up elements which is included by the image pick-up unit 11402 may be one (single-plate type) or a plural number (multi-plate type). Where the image pick-up unit 11402 is configured as that of the multi-plate type, for example, image signals corresponding to respective R, G and B are generated by the image pickup elements, and the image signals may be synthesized to obtain a color image. The image pick-up unit 11402 may also be configured so as to have a pair of image pick-up elements for acquiring respective image signals for the right eye and the left eye ready for three-dimensional (3D) display. If 3D display is performed, then the depth of a living body tissue in a surgical region can be comprehended more accurately by the surgeon 11131. It is to be noted that, where the image pickup unit 11402 is configured as a stereoscopic type, a plurality of systems of lens units 11401 are provided corresponding to the individual image pick-up elements.

Further, the image pick-up unit 11402 may not necessarily be provided on the camera head 11102. For example, the image pick-up unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked-up image by the image pick-up unit 11402 can be suitably adjusted.

The communication unit 11404 includes a communication apparatus for transmitting and receiving various kinds of information to and from the CCU 11201. The communication unit 11404 transmits an image signal acquired from the image pick-up unit 11402 as raw data to the CCU 11201 through the transmission cable 11400.

In addition, the communication unit 11404 receives a control signal for driving the camera head 11102 from the CCU 11201 and supplies the control signal to the camera head controlling unit 11405. The control signal includes information relating to image pick-up conditions such as, for example, information that a frame rate of a picked-up image is designated, information that an exposure value upon image pick-up is designated and/or information that a magnification and a focal point of a picked-up image are designated.

It is to be noted that the image pick-up conditions such as the frame rate, exposure value, magnification or focal point may be designated by the user or may be set automatically by the control unit 11413 of the CCU 11201 based on an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 based on a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for driving of the camera head 11102 to the camera head 11102. The image signal and the control signal can be transmitted by electrical communication, optical communication, or the like.

The image processing unit 11412 performs various image processes for an image signal in the form of raw data transmitted thereto from the camera head 11102.

The control unit 11413 performs various kinds of control processes relating to image picking up of a surgical region, or the like, by the endoscope 11100 and display of the picked-up image, or the like. For example, the control unit 11413 creates a control signal for driving of the camera head 11102.

Further, the control unit 11413 controls, based on an image signal for which image processes have been performed by the image processing unit 11412, the display apparatus 11202 to display a picked-up image in which the surgical region or the like is imaged. Thereupon, the control unit 11413 may recognize various objects in the picked-up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked-up image. The control unit 11413 may cause, when controlling the display apparatus 11202 to display a picked-up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both electrical and optical communications.

Here, while, in the example depicted, communication is performed by wired communication using the transmission cable 11400, the communication between the camera head 11102 and the CCU 11201 may, however, be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pick-up unit 11402 provided in the camera head 11102 of the endoscope 11100 of the configurations described above. Applying the technology according to an embodiment of the present disclosure to the image pick-up unit 11402 enables the image pick-up unit 11402 to have high sensitivity, thus making it possible to provide the endoscope 11100 having high definition.

Although the description has been given hereinabove of the present disclosure with reference to the embodiment, the modification examples, the application example, and the practical application examples, the present technology is not limited to the foregoing embodiment and the like and may be modified in a wide variety of ways. For example, although the foregoing modification examples have been described as modification examples of the foregoing embodiment, the configurations of the respective modification examples may be combined as appropriate.

In the foregoing embodiment and the like, the imaging device is exemplified and described; however, it is sufficient for the photodetector of the present disclosure, for example, to receive incident light and convert the light into electrical charge. The output signal may be a signal of image information or a signal of ranging information. The photodetector (imaging device) is applicable to an image sensor, a distance measurement sensor, or the like.

The photodetector according to the present disclosure is applicable also as a distance measurement sensor enabling distance measurement of a time-of-flight (TOF) method. The photodetector (imaging device) is applicable also as a sensor enabling detection of an event, e.g., an event-driven sensor (referred to as an Event Vision Sensor (EVS), an Event Driven Sensor (EDS), a Dynamic Vision Sensor (DVS), etc.).

The light-guiding section 50, which is an optical element, may be configured as a lens section that condenses light through design of the structure 30. In addition, the light-guiding section 50 may be configured as a filter section that selectively transmits light of a particular wavelength region of incoming light. The photodetector and the optical element (light-guiding section 50) according to the present disclosure are applicable to various apparatuses.

The photodetector of an embodiment of the present disclosure includes: a light-guiding section including a structure including a first section having a size equal to or less than a wavelength of incident light and a second section provided below the first section, a first material provided next to the first section and having a refractive index different from a refractive index of the structure, and a second material provided next to the second section and having a refractive index different from the refractive index of the structure; and a first photoelectric conversion section that photoelectrically converts light incident via the light-guiding section. The first section is in contact with the second section. It is therefore possible to control the shape of the structure, thus making it possible to suppress a decrease in sensitivity to the oblique incident light. It is possible to implement the photodetector having favorable detection performance.

The optical element of an embodiment of the present disclosure includes: a structure including a first section having a size equal to or less than a wavelength of incident light and a second section provided below the first section; a first material provided next to the first section and having a refractive index different from a refractive index of the structure; and a second material provided next to the second section and having a refractive index different from the refractive index of the structure. The first section is in contact with the second section. It is to be noted that, here, the phrase “in contact” includes a case of being in direct contact as well as a case of being in contact, with a natural oxide film or the like interposed therebetween. According to the optical element of the present disclosure, it is possible to control the shape of the structure. In addition, it is possible to improve characteristics for the oblique incident light.

It is to be noted that the effects described herein are merely exemplary and are not limited to the description and may further include other effects. In addition, the present disclosure may also have the following configurations.
(1) A photodetector including:
a light-guiding section including a structure including a first section and a second section, a first material, and a second material, the first section having a size equal to or less than a wavelength of incident light, the second section provided below the first section, the first material provided next to the first section and having a refractive index different from a refractive index of the structure, the second material provided next to the second section and having a refractive index different from the refractive index of the structure; and
a first photoelectric conversion section that photoelectrically converts light incident via the light-guiding section, in which the first section is in contact with the second section.
(2) The photodetector according to (1), in which the first material is in contact with the second material.
(3) The photodetector according to (1) or (2), in which the first material and the second material include materials different from each other.
(4) The photodetector according to any one of (1) to (3), in which the first material and the second material have thicknesses different from each other in a stacking direction of the first material and the second material.
(5) The photodetector according to any one of (1) to (4), in which the first section and the second section are provided continuously.
(6) The photodetector according to any one of (1) to (5), in which the first section and the second section have sizes different from each other.
(7) The photodetector according to any one of (1) to (6), further including a light-receiving section including a plurality of the first photoelectric conversion sections, in which a distance from a center of the first section to a center of the second section differs depending on a distance from a center of the light-receiving section.
(8) The photodetector according to any one of (1) to (7), in which the structure includes a third section provided below the second section, and the light-guiding section includes a third material provided next to the third section and having a refractive index different from a refractive index of the third section.
(9) The photodetector according to (8), in which the second section and the third section have sizes different from each other.
(10) The photodetector according to (8) or (9), further including the light-receiving section including the plurality of the first photoelectric conversion sections, in which a distance from the center of the second section to a center of the third section differs depending on a distance from the center of the light-receiving section.
(11) The photodetector according to any one of (1) to (10), in which the light-guiding section is provided above the first photoelectric conversion section and disperses incident light.
(12) The photodetector according to any one of (1) to (11), further including a second photoelectric conversion section that is provided next to the first photoelectric conversion section and photoelectrically converts light incident via the light-guiding section, in which the light-guiding section guides light of a first wavelength, of the incident light, to a side of the first photoelectric conversion section and guides light of a second wavelength to a side of the second photoelectric conversion section.
(13) The photodetector according to (12), further including a third photoelectric conversion section that is provided next to the first photoelectric conversion section and photoelectrically converts light incident via the light-guiding section, in which the light-guiding section guides light of a third wavelength, of the incident light, to a side of the third photoelectric conversion section.
(14) The photodetector according to any one of (1) to (13), in which the first section and the second section each have a size equal to or less than a wavelength of visible light.
(15) The photodetector according to any one of (1) to (14), further including a lens which is provided over the light-guiding section and on which light is incident, in which the first photoelectric conversion section photoelectrically converts light transmitted through the lens and the light-guiding section.
(16) The photodetector according to any one of (1) to (15), further including a color filter provided between the light-guiding section and the first photoelectric conversion section, in which the first photoelectric conversion section photoelectrically converts light transmitted through the color filter.
(17) An electronic apparatus including:
an optical system; and
a photodetector that receives light transmitted through the optical system,
the photodetector including
a light-guiding section including a structure including a first section and a second section, a first material, and a second material, the first section having a size equal to or less than a wavelength of incident light, the second section provided below the first section, the first material provided next to the first section and having a refractive index different from a refractive index of the structure, the second material provided next to the second section and having a refractive index different from the refractive index of the structure, and
a photoelectric conversion section that photoelectrically converts light incident via the light-guiding section, in which the first section is in contact with the second section.
(18) An optical element including:
a structure including a first section and a second section, the first section having a size equal to or less than a wavelength of incident light, the second section being provided below the first section;
a first material provided next to the first section and having a refractive index different from a refractive index of the structure; and
a second material provided next to the second section and having a refractive index different from the refractive index of the structure, in which the first section is in contact with the second section.
(19) A photodetector, comprising:
a light-guide including:
a structure including a first section and a second section;
a first material; and
a second material,
wherein the first section has a size equal to or less than a wavelength of incident light,
wherein the second section is provided below the first section, wherein the first material is provided next to the first section and has having a refractive index different from a refractive index of the structure, and
wherein the second material is provided next to the second section and has having a refractive index different from the refractive index of the structure; and
a first photoelectric converter that photoelectrically converts the incident light via the light-guide,
wherein the first section is in contact with the second section.
(20) The photodetector according to (19), wherein the first material is in contact with the second material.
(21) The photodetector according to (19) or (20), wherein the first material and the second material include materials different from each other.
(22) The photodetector according to (19) to (21), wherein the first material and the second material have thicknesses different from each other in a stacking direction of the first material and the second material.
(23) The photodetector according to (19) to (22), wherein the first section and the second section are provided continuously.
(24) The photodetector according to (19) to (23) wherein the first section and the second section have sizes different from each other.
(25) The photodetector according to (19) to (24), further comprising:
a light-receiver including a plurality of the first photoelectric converters,
wherein a distance from a center of the first section to a center of the second section differs depending on a distance from a center of the light-receiver.
(26) The photodetector according to (19) to (25), wherein the structure includes a third section provided below the second section, and the light guide includes a third material provided next to the third section and having a refractive index different from a refractive index of the third section.
(27) The photodetector according to (26), wherein the second section and the third section have sizes different from each other.
(28) The photodetector according to (26) or (27), further comprising:
a light receiver including a plurality of the first photoelectric converters,
wherein a distance from a center of the second section to a center of the third section differs depending on a distance from a center of the light-receiver.
(29) The photodetector according to (19) to (28), wherein the light-receiver is provided above the first photoelectric converter and disperses incident light.
(30) The photodetector according to (19) to (29), further comprising:
a second photoelectric converter that is provided next to the first photoelectric converter and photoelectrically converts incident light via the light-guide,
wherein the light-guide guides incident light of a first wavelength to the first photoelectric converter and guides incident light of a second wavelength to the second photoelectric converter.
(31) The photodetector according to (30), further comprising:
a third photoelectric converter that is provided next to the first photoelectric converter and photoelectrically converts incident light via the light-guide,
wherein the light-guide guides incident light of a third wavelength to the third photoelectric converter.
(32) The photodetector according to (19) to (31), wherein the first section and the second section each have a size equal to or less than a wavelength of visible light.
(33) The photodetector according to (19) to (32), further comprising:
a lens which is provided over the light-guide and on which incoming light is incident,
wherein the first photoelectric converter photoelectrically converts light transmitted through the lens and the light-guide.
(34) The photodetector according to (19) to (33), further comprising:
a color filter provided between the light-guide and the first photoelectric converter,
wherein the first photoelectric converter photoelectrically converts incoming light transmitted through the color filter.
(35) An electronic apparatus, comprising:
an optical system; and
a photodetector that receives light transmitted through the optical system,
wherein the photodetector includes:
a light-guide including:
a structure including a first section and a second section;
a first material; and
a second material,
wherein the first section has a size equal to or less than a wavelength of incident light,
wherein the second section is provided below the first section,
wherein the first material is provided next to the first section and has a refractive index different from a refractive index of the structure, and
wherein the second material is provided next to the second section and has a refractive index different from the refractive index of the structure, and
a photoelectric converter that photoelectrically converts the incident light via the light-guide,
wherein the first section is in contact with the second section.
(36) An optical element, comprising:
a structure including a first section and a second section,
wherein the first section has a size equal to or less than a wavelength of incident light, and
wherein the second section is provided below the first section;
a first material provided next to the first section and having a refractive index different from a refractive index of the structure; and
a second material provided next to the second section and having a refractive index different from the refractive index of the structure,
wherein the first section is in contact with the second section.
(37) The optical element according to (36), wherein the first material is in contact with the second material.
(38) The optical element according to (36) or (37), wherein the first material and the second material include materials different from each other.

It should be understood by those skilled in the art that various modifications, combinations, sub-combinations and alterations may occur depending on design requirements and other factors insofar as they are within the scope of the appended claims or the equivalents thereof.

### REFERENCE NUMERALS LIST

1 imaging device
10 light-receiving section
12 photoelectric conversion section
20 transparent layer
25 color filter
30 structure
31 first section
32 second section
41 first member
42 second member
50 light-guiding section
100 pixel section

What is claimed is:

1. A photodetector, comprising:
a light-guide including:
a structure including a first section and a second section;
a first material; and
a second material,
wherein the first section has a size equal to or less than a wavelength of incident light,
wherein the second section is provided below the first section, wherein the first material is provided next to the first section and has having a refractive index different from a refractive index of the structure, and
wherein the second material is provided next to the second section and has having a refractive index different from the refractive index of the structure; and
a first photoelectric converter that photoelectrically converts the incident light via the light-guide,
wherein the first section is in contact with the second section.

2. The photodetector according to claim 1, wherein the first material is in contact with the second material.

3. The photodetector according to claim 1, wherein the first material and the second material include materials different from each other.

4. The photodetector according to claim 1, wherein the first material and the second material have thicknesses different from each other in a stacking direction of the first material and the second material.

5. The photodetector according to claim 1, wherein the first section and the second section are provided continuously.

6. The photodetector according to claim 1, wherein the first section and the second section have sizes different from each other.

7. The photodetector according to claim 1, further comprising:
a light-receiver including a plurality of the first photoelectric converters,
wherein a distance from a center of the first section to a center of the second section differs depending on a distance from a center of the light-receiver.

8. The photodetector according to claim 1, wherein the structure includes a third section provided below the second section, and the light guide includes a third material provided next to the third section and having a refractive index different from a refractive index of the third section.

9. The photodetector according to claim 8, wherein the second section and the third section have sizes different from each other.

10. The photodetector according to claim 8, further comprising:
a light receiver including a plurality of the first photoelectric converters,
wherein a distance from a center of the second section to a center of the third section differs depending on a distance from a center of the light-receiver.

11. The photodetector according to claim 1, wherein the light-receiver is provided above the first photoelectric converter and disperses incident light.

12. The photodetector according to claim 1, further comprising:
a second photoelectric converter that is provided next to the first photoelectric converter and photoelectrically converts incident light via the light-guide,
wherein the light-guide guides incident light of a first wavelength to the first photoelectric converter and guides incident light of a second wavelength to the second photoelectric converter.

13. The photodetector according to claim 12, further comprising:
a third photoelectric converter that is provided next to the first photoelectric converter and photoelectrically converts incident light via the light-guide,
wherein the light-guide guides incident light of a third wavelength to the third photoelectric converter.

14. The photodetector according to claim 1, wherein the first section and the second section each have a size equal to or less than a wavelength of visible light.

15. The photodetector according to claim 1, further comprising:
a lens which is provided over the light-guide and on which incoming light is incident,
wherein the first photoelectric converter photoelectrically converts light transmitted through the lens and the light-guide.

16. The photodetector according to claim 1, further comprising:
a color filter provided between the light-guide and the first photoelectric converter,
wherein the first photoelectric converter photoelectrically converts incoming light transmitted through the color filter.

17. An electronic apparatus, comprising:
an optical system; and
a photodetector that receives light transmitted through the optical system,
wherein the photodetector includes:
a light-guide including:
a structure including a first section and a second section;
a first material; and
a second material,
wherein the first section has a size equal to or less than a wavelength of incident light,
wherein the second section is provided below the first section,
wherein the first material is provided next to the first section and has a refractive index different from a refractive index of the structure, and
wherein the second material is provided next to the second section and has a refractive index different from the refractive index of the structure, and
a photoelectric converter that photoelectrically converts the incident light via the light-guide,
wherein the first section is in contact with the second section.

18. An optical element, comprising:
a structure including a first section and a second section,
wherein the first section has a size equal to or less than a wavelength of incident light, and
wherein the second section is provided below the first section;
a first material provided next to the first section and having a refractive index different from a refractive index of the structure; and
a second material provided next to the second section and having a refractive index different from the refractive index of the structure,
wherein the first section is in contact with the second section.

19. The optical element according to claim 18, wherein the first material is in contact with the second material.

20. The optical element according to claim 18, wherein the first material and the second material include materials different from each other.
